(19) United States
(12) Patent Application Publication
(10) Pub. No.: US 2025/0070680 A1
(43) Pub. Date: Feb. 27, 2025

(54) DIRECT CURRENT VOLTAGE SAMPLING CIRCUIT USED FOR MEDIUM-VOLTAGE POWER MODULE

(71) Applicant: Eaton Intelligent Power Limited, Dublin 4 (IE)

(72) Inventors: Jianxiong Yu, Shanghai (CN); Jiajie Duan, Shanghai (CN); Cheng Luo, Shanghai (CN); Cheng Wang, Shanghai (CN)

(21) Appl. No.: 18/809,718

(22) Filed: Aug. 20, 2024

(30) Foreign Application Priority Data
Aug. 23, 2023 (CN) 202322284173.8

(51) Int. Cl. H02M 3/335; H02M 1/00

(52) U.S. Cl. CPC H02M 3/33576; H02M 1/007

(57) ABSTRACT

Provided is a direct current voltage sampling circuit used for a medium-voltage power module. The medium-voltage power module includes two cascaded H-bridge circuits. The sampling circuit includes two sampling sub-circuits, with each connected to one H-bridge circuit. The sampling sub-circuit includes: a voltage dividing circuit connected in parallel to an output end of the H-bridge circuit, an isolation module connected to the voltage dividing circuit, a direct current isolated power supply which supplies power to the isolation module independently of the H-bridge circuit, and an amplifier conditioning module which converts an isolated voltage signal into a sampled voltage output. Parasitic capacitances of the isolation module and the direct current isolated power supply are both less than 2 pF, and the sampled voltage outputs of the two sampling sub-circuits are provided to a same local controller. The sampling circuit can suppress the impact of circulation components between two direct current buses in double cascaded bridges, making sampling results more accurate.

### CROSS REFERENCE TO RELATED APPLICATION

This application claims priority to Chinese Patent Application No. 202322284173.8, filed Aug. 23, 2023, the content of which is hereby incorporated herein by reference in its entirety.

### TECHNICAL FIELD

The disclosure belongs to the field of power converters, and in particular, relates to a direct current voltage sampling circuit used for a medium-voltage power module of a medium-voltage power converter.

### BACKGROUND

Conventional power transformers require a lot of materials such as copper and iron, operate at low frequencies, are huge in volume, have problems of core saturation, direct current bias, excitation surges, significant losses, and the like, and also do not have the capabilities of harmonic suppression and fault protection transfer. To meet power supply requirements of high-power direct current loads such as data centers and electric vehicle chargers, medium-voltage power converters have received wide attention. Compared with conventional power transformers, the medium-voltage power converters are a power electronic solution with high distribution efficiency and small volume, need to implement power conversion from a medium-voltage alternating current grid to low-voltage direct current or alternating current, and can have better performance in ultra-large-scale power applications. In modular solutions, as an operating front end of a medium-voltage power converter, two cascaded H-bridges can be integrated in a medium-voltage power module, which can reduce usage costs of a system on raw materials and controllers. Just because of the integration of two H-bridges in a medium-voltage power module, a plurality of circulation loops are produced among a direct current bus, a sampling circuit, and a parasitic circuit. Input voltage of an operational amplifier in the sampling circuit of the conventional medium-voltage power module will be affected by circulation components between direct current buses of two cascaded circuits. Even if an output end of the medium-voltage power module is not loaded, there are still 50 Hz voltage ripples and high-frequency disturbances in sampling values of direct current voltage.

### SUMMARY

Therefore, the objective of the utility model is to overcome the above shortcomings of existing technologies and provide a sampling circuit used for a medium-voltage power converter, which can suppress the impact of a plurality of circulation circuits produced among a direct current bus, a sampling circuit, and a parasitic circuit.

The disclosure provides a direct current voltage sampling circuit used for a medium-voltage power module, the medium-voltage power module includes two cascaded H-bridge circuits, the sampling circuit includes two sampling sub-circuits, each of the sampling sub-circuits is connected to one H-bridge circuit, and the sampling sub-circuit includes: a voltage dividing circuit connected in parallel to an output end of the H-bridge circuit to provide a divided voltage of a direct current voltage input by the H-bridge; an isolation module connected to the voltage dividing circuit to provide an output isolated from the divided voltage; a direct current isolated power supply, which supplies power to the isolation module independently of the H-bridge circuit; and an amplifier conditioning module connected to the isolation module to convert an isolated voltage signal into a sampled voltage output, wherein parasitic capacitances of the isolation module and the direct current isolated power supply are both less than 2 pF, and the sampled voltage outputs of the two sampling sub-circuits are provided to a same local controller.

In some embodiments, the parasitic capacitances of the isolation module and the direct current isolated power supply are both less than 1.7 pF.

In some embodiments, the isolation module is a magnetic coupling isolation amplifier, a capacitive coupling isolation amplifier, or an optical coupling isolation amplifier.

In some embodiments, the voltage dividing circuit includes a first voltage dividing resistor and a second voltage dividing resistor connected in series; and the isolation module is connected in parallel to two ends of the first voltage dividing resistor, where a ratio of resistance of the first voltage dividing resistor to resistance of the second voltage dividing resistor ranges from 0.02 to 0.1.

In some embodiments, the voltage dividing circuit includes a first voltage dividing resistor, a second voltage dividing resistor, and a third voltage dividing resistor sequentially connected in series; and the isolation module is connected in parallel to two ends of the first voltage dividing resistor or the third voltage dividing resistor, where a ratio of resistance of the first voltage dividing resistor to resistance of the second voltage dividing resistor ranges from 0.02 to 0.1; and a ratio of resistance of the third voltage dividing resistor to resistance of the second voltage dividing resistor ranges from 0.02 to 0.1.

In some embodiments, the amplifier conditioning module converts the isolated voltage signal into the sampled voltage output in a form of an analog signal.

In some embodiments, the amplifier conditioning module converts the isolated voltage signal into the sampled voltage output in a form of a digital signal.

Compared with the existing technologies, an isolation amplifier and an isolated power supply both with low parasitic capacitances are added to the direct current sampling circuit of the disclosure, which breaks the impact of circulation loops appearing in the existing sampling circuit on sampling results, forms a short-circuit circulating current path, and suppresses the impact of a plurality of circulation loops among a direct current bus, a sampling circuit, and a parasitic circuit, making the sampling results more accurate.

### BRIEF DESCRIPTION OF THE DRAWINGS

Embodiments of the disclosure will be further explained below with reference to the accompanying drawings.

FIG. 1 is a schematic diagram of a partial circuit structure of a medium-voltage power converter;

FIG. 2 is a schematic diagram of a partial circuit structure of a medium-voltage power module in a power chain of the medium-voltage power converter;

FIG. 3 is a schematic diagram of a structure of a sampling circuit of a medium-voltage power module used for a medium-voltage power converter in existing technologies;

FIG. 4 is a diagram of a direct current voltage sampled waveform using the sampling circuit in the existing technologies;

FIG. 5 is a schematic diagram of a functional composition of a direct current voltage sampling sub-circuit used for a medium-voltage power module according to an embodiment of the disclosure;

FIG. 6 is a schematic diagram of a structure of a direct current voltage sampling circuit of a medium-voltage power module used for a medium-voltage power converter according to a first embodiment of the disclosure;

FIG. 7 is a schematic diagram of a structure of a direct current voltage sampling circuit of a medium-voltage power module used for a medium-voltage power converter according to a second embodiment of the disclosure; and

FIG. 8 is a schematic diagram of a structure of a direct current voltage sampling circuit of a medium-voltage power module used for a medium-voltage power converter according to a third embodiment of the disclosure.

### DETAILED DESCRIPTION

In order to make the objectives, technical solutions, and advantages of the disclosure clearer, the following further explains the disclosure in detail through specific embodiments in conjunction with the accompanying drawings. In the drawings, the same reference numerals represent the same components. It should be understood that the specific embodiments described here are only intended to explain the disclosure, but not to limit the disclosure.

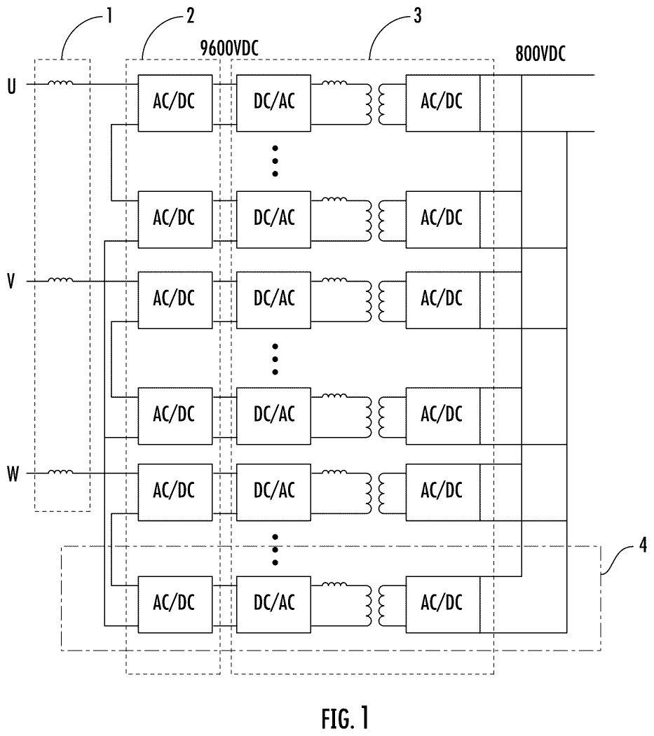

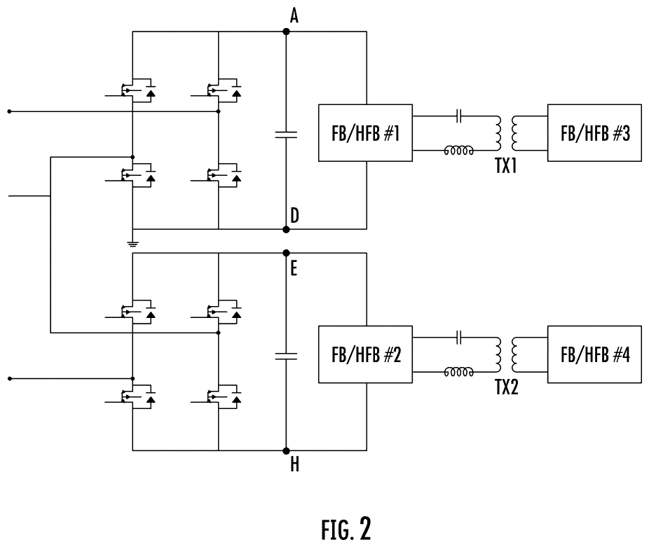

With reference to a schematic diagram of a partial circuit structure of a medium-voltage power converter shown in FIG. 1, the medium-voltage power converter includes: a filter reactor 1, a bypass circuit based on series IGBTs or parallel thyristors (not shown in FIG. 1), a rectifier circuit based on cascaded full bridges 2, and an isolated direct current converter 3. The dashed box 4 in FIG. 1 represents a power chain, and FIG. 2 shows a partial circuit structure of the power chain.

With reference to FIG., 2 which is a schematic diagram of a partial circuit structure of a medium-voltage power module in a power chain of the medium-voltage power converter, two H-bridges can be integrated in one medium-voltage power module. In this case, one medium-voltage power module can be connected to one local controller and one alternating current input terminal used for shielding an electric field, so as to reduce the costs of controllers and raw materials. A sampling circuit in the disclosure collects direct current voltage between two ends of the H-bridges, namely, between A and D and between E and H.

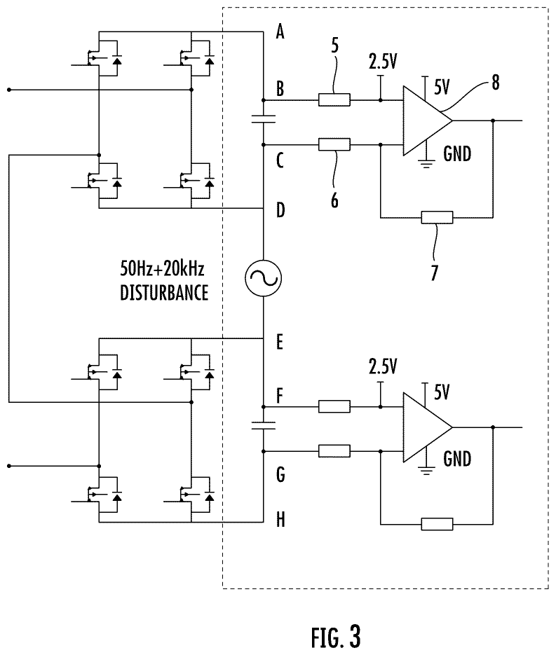

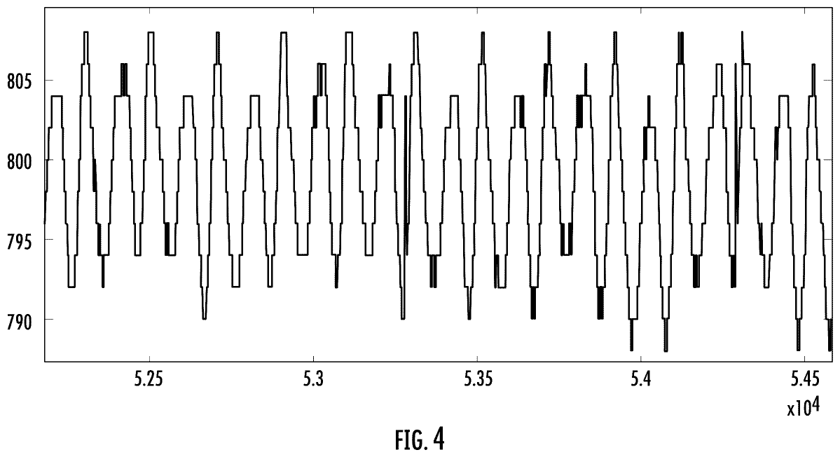

Based on the structure of the medium-voltage power module in FIG. 2, refer to FIG. 3 which is a schematic diagram of a structure of a sampling circuit of a medium-voltage power module used for a medium-voltage power converter in existing technologies, including: a forward input end of an operational amplifier 8 is connected to a first resistor 5 and a 2.5V direct current power source respectively, a reverse input end of the operational amplifier 8 is connected to a second resistor 6, a third resistor 7 is connected in parallel between the reverse input end and a output end of the operational amplifier 8, and a 5V direct current power source supplies power to the operational amplifier 8. The other end of the first resistor 5 and the other end of the second resistor 6 are connected to two ends of an H-bridge respectively, namely, B and C. The output end of the operational amplifier 8 outputs sampled voltage of a medium-voltage power module. Because a plurality of circulation loops are produced between direct current buses of two cascaded circuits, such as A-B-2.5V-F-E-D-C-B-A, B-2.5V-F-E-D-C-B, and C-B-2.5V-F-E-D-C, input voltage of the operational amplifier 8 will be affected by circulation components between the direct current buses of the two cascaded circuits. Even if the output end of the medium-voltage power module is not loaded, there are still 50 Hz voltage ripples and 20 kHz high-frequency disturbances in sampled values of direct current voltage (as shown in a direct current voltage sampled waveform in FIG. 4).

In order to eliminate the impact of circulation components, the disclosure provides a sampling circuit, which can break circulation loops produced between direct current buses of two cascaded circuits. The following will introduce a sampling circuit of a medium-voltage power module used for a medium-voltage power converter of the disclosure through specific embodiments.

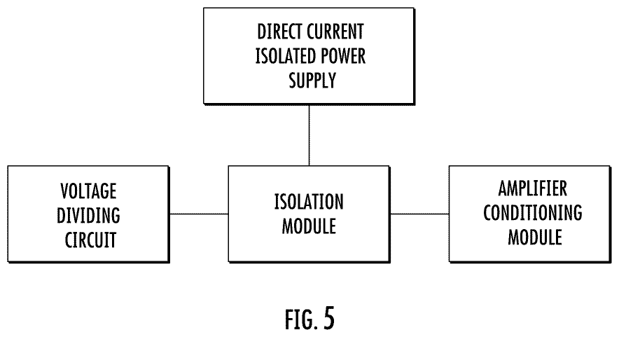

As shown in FIG. 5, an embodiment of the disclosure provides a direct current voltage sampling circuit used for a medium-voltage power module. The sampling circuit includes two sampling sub-circuits, each of the sampling sub-circuits is connected to one H-bridge circuit, and the sampling sub-circuit includes: a voltage dividing circuit connected in parallel to an output end of the H-bridge circuit to provide a divided voltage of a direct current voltage input by the H-bridge; an isolation module connected to the voltage dividing circuit to provide an output isolated from the divided voltage; a direct current isolated power supply, which supplies power to the isolation module independently of the H-bridge circuit; and an amplifier conditioning module connected to the isolation module to convert an isolated voltage signal into a sampled voltage output, where parasitic capacitances of the isolation module and the direct current isolated power supply are both less than 2 pF, and the sampled voltage outputs of the two sampling sub-circuits are provided to a same local controller.

### First Embodiment

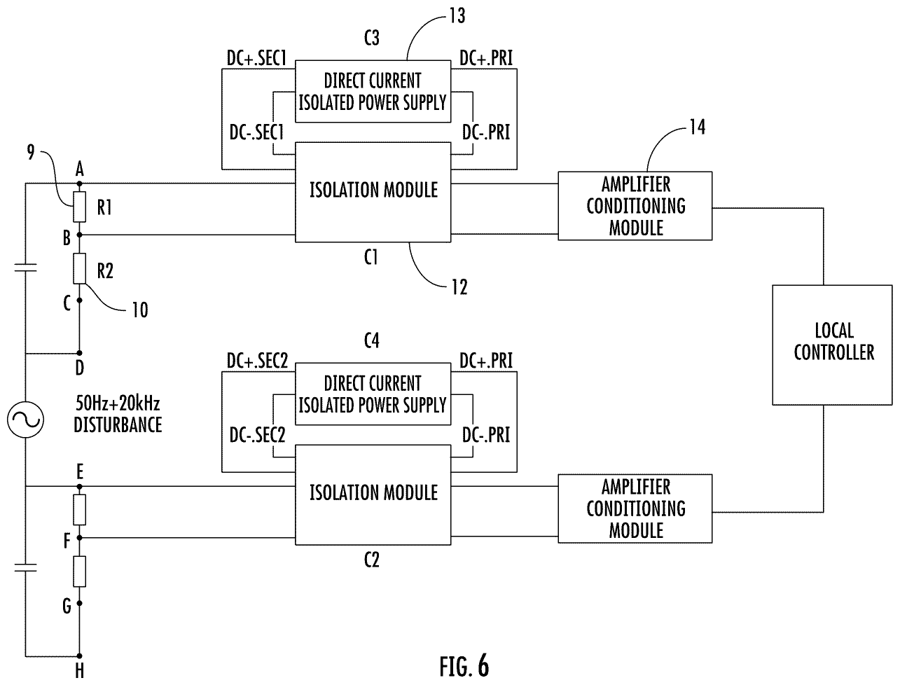

With reference to FIG. 6 which is a schematic diagram of a structure of a direct current voltage sampling circuit of a medium-voltage power module used for a medium-voltage power converter according to a first embodiment of the disclosure, the sampling circuit includes two sampling sub-circuits, each of which is connected to one H-bridge circuit to collect output voltage of a medium-voltage power module in a medium-voltage power converter. The sampling sub-circuit includes: a voltage dividing circuit connected in parallel to an output end of the H-bridge circuit, namely, a first voltage dividing resistor 9 and a second voltage dividing resistor 10 connected in series; an isolation module 12 connected in parallel to the first voltage dividing resistor 9; and a direct current isolated power supply 13, which supplies power to two ends of the isolation module 12 respectively, where an output end of the isolation module 12 is connected to an input end of an amplifier conditioning module 14, and the amplifier conditioning module 14 converts an isolated voltage signal into a sampled voltage output. In some embodiments, the amplifier conditioning module converts the isolated voltage signal into the sampled voltage output in a form of an analog signal or a digital signal. The sampled voltage outputs of the two sampling sub-circuits are provided to a same local controller, which can ensure more accurate sampled signals under the condition that two H-bridges are cascaded and share sampling, conditioning, and control power source. The isolation module 12 can isolate disturbances in the output voltage of the H-bridge circuit. The isolation module 12 may be a magnetic coupling isolation amplifier, a capacitive coupling isolation amplifier, or an optical coupling isolation amplifier. Parasitic capacitances of the isolation module 12 and the direct current isolated power supply 13 need to be low enough. After inventor's research, the effect of this embodiment can be achieved when their parasitic capacitances are less than 2 pF. In some embodiments, the parasitic capacitances of the isolation module 12 and the direct current isolated power supply 13 need to be less than 1.7 pF. In some embodiments, a ratio of resistance of the first voltage dividing resistor 9 to resistance of the second voltage dividing resistor 10 ranges from 0.02 to 0.1. In the disclosure, an isolation amplifier and an isolated power supply both with low parasitic capacitances are added to break circulation loops and to form a short-circuit circulating current path. 50 Hz voltage ripples and voltage drop of a switching frequency component on the first voltage dividing resistor 9 are extremely low, and the obtained sampled voltage is acceptable, thereby suppressing the impact of circulation components between two direct current buses in double cascaded bridges.

### Second Embodiment

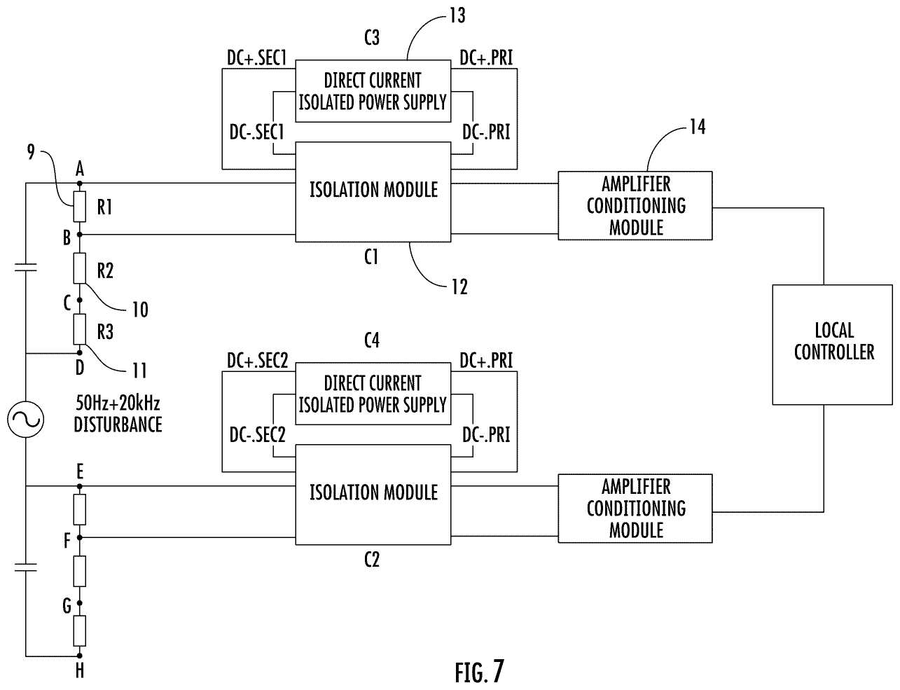

With reference to FIG. 7 which is a schematic diagram of a structure of a direct current voltage sampling circuit of a medium-voltage power module used for a medium-voltage power converter according to a second embodiment of the disclosure, the sampling circuit includes two sampling sub-circuits, each of which is connected to one H-bridge circuit to collect output voltage of a medium-voltage power module in a medium-voltage power converter. The sampling sub-circuit includes: a voltage dividing circuit connected in parallel to an output end of the H-bridge circuit, namely, a first voltage dividing resistor 9, a second voltage dividing resistor 10, and a third voltage dividing resistor 11 sequentially connected in series; an isolation module 12 connected in parallel to the first voltage dividing resistor 9; and a direct current isolated power supply 13, which supplies power to two ends of the isolation module 12 respectively, where an output end of the isolation module 12 is connected to an input end of an amplifier conditioning module 14, and the amplifier conditioning module 14 outputs sampled voltage of the medium-voltage power module. The sampled voltage outputs of the two sampling sub-circuits are provided to a same local controller.

### Third Embodiment

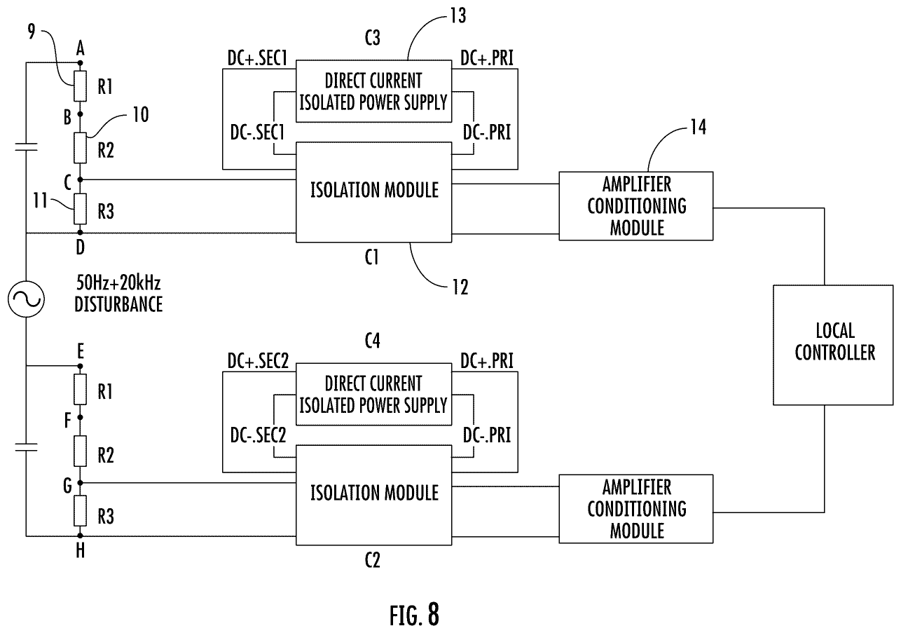

With reference to FIG. 8 which is a schematic diagram of a structure of a direct current voltage sampling circuit of a medium-voltage power module used for a medium-voltage power converter according to a third embodiment of the disclosure, the sampling circuit includes two sampling sub-circuits, each of which is connected to one H-bridge circuit to collect output voltage of a medium-voltage power module in a medium-voltage power converter. The sampling sub-circuit includes: a voltage dividing circuit connected in parallel to an output end of the H-bridge circuit, namely, a first voltage dividing resistor 9, a second voltage dividing resistor 10, and a third voltage dividing resistor 11 sequentially connected in series; an isolation module 12 connected in parallel to the third voltage dividing resistor 11; and a direct current isolated power supply 13, which supplies power to two ends of the isolation module 12 respectively, where an output end of the isolation module 12 is connected to an input end of an amplifier conditioning circuit 14, and the amplifier conditioning circuit 14 outputs sampled voltage of the medium-voltage power module. The sampled voltage outputs of the two sampling sub-circuits are provided to a same local controller.

In the second and third embodiments, parasitic capacitances of the isolation module 12 and the direct current isolated power supply 13 need to be low enough. After inventor's research, the effects of the embodiments can be achieved when their parasitic capacitances are less than 2 pF. In some embodiments, the parasitic capacitances of the isolation module 12 and the direct current isolated power supply 13 need to be less than 1.7 pF. In some embodiments, a ratio of resistance of the first voltage dividing resistor 9 to resistance of the second voltage dividing resistor 10 ranges from 0.02 to 0.1; and a ratio of resistance of the third voltage dividing resistor 11 to resistance of the second voltage dividing resistor 10 ranges from 0.02 to 0.1.

In the disclosure, in order to break the impact of voltage ripples and high-frequency disturbances caused by circulation loops, an isolation amplifier and an isolated power supply with low parasitic capacitances are added. The isolation module 12 can be connected in parallel to the first voltage dividing resistor 9 to measure sampled voltage forward, or the isolation module 12 can be connected in parallel to the third voltage dividing resistor 11 to measure sampled voltage reversely.

Although the disclosure is described through preferred embodiments, the disclosure is not limited to the embodiments described herein and includes various changes and variations made without departing from the scope of the disclosure.

What is claimed is:

1. A direct current voltage sampling circuit used for a medium-voltage power module, the medium-voltage power module comprising two cascaded H-bridge circuits, wherein the current voltage sampling circuit comprises two sampling sub-circuits, each of the sampling sub-circuits is connected to one H-bridge circuit, and the sampling sub-circuit comprises:
a voltage dividing circuit connected in parallel to an output end of the H-bridge circuit to provide a divided voltage of a direct current voltage input by the H-bridge;
an isolation module connected to the voltage dividing circuit to provide an output isolated from the divided voltage;
a direct current isolated power supply, which supplies power to the isolation module independently of the H-bridge circuit; and
an amplifier conditioning module connected to the isolation module to convert an isolated voltage signal into a sampled voltage output,
wherein parasitic capacitances of the isolation module and the direct current isolated power supply are both less than 2 pF, and the sampled voltage outputs of the two sampling sub-circuits are provided to a same local controller.

2. The direct current voltage sampling circuit of claim 1, wherein the parasitic capacitances of the isolation module and the direct current isolated power supply are both less than 1.7 pF.

3. The direct current voltage sampling circuit of claim 1, wherein the isolation module is a magnetic coupling isolation amplifier, a capacitive coupling isolation amplifier, or an optical coupling isolation amplifier.

4. The direct current voltage sampling circuit of claim 1, wherein the voltage dividing circuit comprises a first voltage dividing resistor and a second voltage dividing resistor connected in series;
wherein the isolation module is connected in parallel to two ends of the first voltage dividing resistor; and
wherein a ratio of resistance of the first voltage dividing resistor to resistance of the second voltage dividing resistor ranges from 0.02 to 0.1.

5. The direct current voltage sampling circuit of claim 1, wherein the voltage dividing circuit comprises a first voltage dividing resistor, a second voltage dividing resistor, and a third voltage dividing resistor sequentially connected in series; and the isolation module is connected in parallel to two ends of the first voltage dividing resistor or the third voltage dividing resistor; and
wherein a ratio of resistance of the first voltage dividing resistor to resistance of the second voltage dividing resistor ranges from 0.02 to 0.1; and a ratio of resistance of the third voltage dividing resistor to resistance of the second voltage dividing resistor ranges from 0.02 to 0.1.

6. The direct current voltage sampling circuit of claim 1, wherein the amplifier conditioning module converts the isolated voltage signal into the sampled voltage output in a form of an analog signal.

7. The direct current voltage sampling circuit of claim 1, wherein the amplifier conditioning module converts the isolated voltage signal into the sampled voltage output in a form of a digital signal.
